(19) United States
(12) Patent Application Publication
(10) Pub. No.: US 2025/0192057 A1
(43) Pub. Date: Jun. 12, 2025

(54) ELECTRONIC DEVICE

(71) Applicant: InnoLux Corporation, Miao-Li County (TW)

(72) Inventors: Chandra LIUS, Miao-Li County (TW); Chung-Wen YEN, Miao-Li County (TW); Jhe-Ciou JHU, Miao-Li County (TW)

(21) Appl. No.: 18/941,400

(22) Filed: Nov. 8, 2024

(30) Foreign Application Priority Data
Dec. 11, 2023 (CN) 202311686032.7

(51) Int. Cl. H01L 23/532; H01L 23/528; H01L 27/088; H01L 29/423

(52) U.S. Cl. CPC H01L 23/53295; H01L 23/528; H10D 64/512; H10D 84/83

(57) ABSTRACT

An electronic device is provided. The electronic device includes a substrate, a first insulating layer, an oxide semiconductor layer, a second insulating layer, and a gate electrode. The first insulating layer is disposed on the substrate. The oxide semiconductor layer is disposed on the first insulating layer and has a first part and a second part adjacent to the first part. The second insulating layer is disposed on the oxide semiconductor layer. The gate electrode is disposed on the substrate and overlapped with the first part of the oxide semiconductor layer. Wherein a concentration of H⁻ at a first interface between the second insulating layer and the first part is greater than a concentration of H⁻ at a center portion of the first part in a spectrum measured by TOF-SIMS.

### CROSS REFERENCE TO RELATED APPLICATIONS

This application claims priority of China Patent Application No. CN 202311686032.7, filed on Dec. 11, 2023, the entirety of which is incorporated by reference herein.

### TECHNICAL FIELD

Some embodiments of the present disclosure relate to an electronic device, and, in particular, to an improved electronic device.

### BACKGROUND

Electronic products that include chips, such as displays, smartphones, tablets, notebook computers, and televisions, have become indispensable necessities in modern society. With the booming development of these types of electronic products, consumers have high expectations on their quality, functionality, or price of these electronic products.

Electronic products often include transistors to perform operations. However, due to the need for doping in the process of manufacturing transistors, unnecessary diffusion of dopants may occur, which can reduce the stability of the transistors. Therefore, these electronic products do not meet consumer demand in all respects, and there are still some problems with electronic products that need to be solved. The development of improved electronic devices remains one of the current goals of the industry.

### SUMMARY

In some embodiments, an electronic device is provided. The electronic device includes a substrate, a first insulating layer, an oxide semiconductor layer, a second insulating layer, and a gate electrode. The first insulating layer is disposed on the substrate. The oxide semiconductor layer is disposed on the first insulating layer and has a first part and a second part adjacent to the first part. The second insulating layer is disposed on the oxide semiconductor layer. The gate electrode is disposed on the substrate and overlapped with the first part of the oxide semiconductor layer. Wherein a concentration of H⁻ at a first interface between the second insulating layer and the first part is greater than a concentration of H⁻ at a center portion of the first part in a spectrum measured by TOF-SIMS.

The electronic device of the present disclosure may be applied in various types of electronic apparatus. In order to make the features and advantages of some embodiments of the present disclosure more understand, some embodiments of the present disclosure are listed below in conjunction with the accompanying drawings, and are described in detail as follows.

### BRIEF DESCRIPTION OF THE DRAWINGS

The present disclosure can be more fully understood from the following detailed description when read in conjunction with the accompanying drawings. It should be noted that, according to the standard practice in the industry, the various features are not drawn to scale. In fact, the dimensions of the various features may be arbitrarily increased or reduced for clarity.

FIG. 1 shows a schematic cross-sectional view of an electronic device according to some embodiments of the present disclosure.

FIGS. 2 to 8 respectively show schematic elemental analysis diagrams of an electronic device according to some embodiments of the present disclosure.

### DETAILED DESCRIPTION

Electronic devices of various embodiments of the present disclosure will be described in detail below. It should be understood that the following description provides many different embodiments for implementing various aspects of some embodiments of the present disclosure. The specific components and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding components in order to clearly describe the present disclosure. However, the use of these similar or corresponding reference numerals is only for the purpose of simply and clearly description of some embodiments of the present disclosure, and does not imply any correlation between the different embodiments or structures discussed.

It should be understood that relative terms, such as “lower”, “bottom”, “higher”, or “top” may be used in various embodiments to describe the relative relationship of one component of the drawings to another component. It will be understood that if the device in the drawings were turned upside down, components described on the “lower” side would become components on the “upper” side. The embodiments of the present disclosure can be understood together with the drawings, and the drawings of the present disclosure are also regarded as a portion of the disclosure.

Furthermore, when it is mentioned that a first material layer is located “on” or “over” a second material layer, it may include the embodiment which the first material layer and the second material layer are in direct contact and the embodiment which the first material layer and the second material layer are not in direct contact with each other, that is one or more layers of other materials is between the first material layer and the second material layer. However, if the first material layer is directly on the second material layer, it means that the first material layer and the second material layer are in direct contact.

In addition, it should be understood that ordinal numbers such as “first”, “second”, and the like used in the description and claims are used to modify components and are not intended to imply and represent the component(s) have any previous ordinal numbers, and do not represent the order of a certain component and another component, or the order of the manufacturing method, and the use of these ordinal numbers is only used to clearly distinguished an component with a certain name and another component with the same name. The claims and the specification may not use the same terms, for example, a first component in the specification may be a second component in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to bonding and connection can also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The phrase “a range between a first value and a second value” or “a first value to a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Certain terms may be used throughout the specification and claims in the present disclosure to refer to specific components. A person of ordinary skills in the art should be understood that electronic device manufacturers may refer to the same component by different terms. The present disclosure does not intend to distinguish between components that have the same function but with different terms. In the following description and claims, terms such as “including”, “comprising”, and “having” are open-ended words, so they should be interpreted as meaning “including but not limited to . . . ”. Therefore, when the terms “including”, “comprising”, and/or “having” is used in the description of the present disclosure, it designates the presence of corresponding features, regions, steps, operations, and/or components, but does not exclude the presence of one or more corresponding features, regions, steps, operations, and/or components.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For convenience of description, hereinafter, the X-axis direction is the first direction D1 and the Z-axis direction is the second direction D2. In some embodiments, the schematic cross-sectional views described herein are schematic views of the XZ plane. In some embodiments, a normal direction of the substrate is the second direction D2.

It should be understood that, according to the embodiments of the present disclosure, relative setting relationship between components, a depth, a thickness, a width, or a height of each component, and a spacing or a distance between components may be measured by using an optical microscope (OM), a scanning electron microscope (SEM), a film thickness profiler (α-step), ellipsometer, or other suitable methods. According to some embodiments, a cross-sectional structure image including a component to be measured may be obtained by using the scanning electron microscope, and then the depth, the thickness, the width, or the height of the component, and the spacing or the distance between components may be measured.

It should be understood that according to embodiments of the present disclosure, time of flight secondary ion mass spectrometer (TOF-SIMS) or other suitable mass spectrometry methods may be used to quantitatively analyze and/or qualitative analysis of the elements in each component. According to some embodiments, a sample including an element to be measured may be obtained from an electronic device, and the elements in the sample may be analyzed. In some embodiments, the sample may be analyzed by using TOF-SIMS in negative ion mode, TOF-SIMS in positive ion mode, or a combination thereof. In some embodiments, the concentration of the sample that may be obtained depends on the accuracy of the analytical method used, and different analytical methods may have different minimum analyzable values. When the concentration of an element in the sample is less than the minimum analyzable value, it may only qualitatively analyze whether the element exists and describe the relative content relationship between the element and other elements, but it cannot quantitatively analyze the concentration of the element. In other words, the element may be substantially absent from the sample, that is, the concentration of the element is substantially equal to 0, or the element may be substantially included in the sample, that is, the concentration of the element is substantially greater than 0, but the concentration of the element is lower than the minimum analyzable value.

It should be understood that in the following, the unit of concentration “atoms/c.c.” represents the number of atoms included per cubic centimeter. In the following, when it is described that “the concentration of an element in the first component (or in the first part, or at the first interface) is greater than the concentration of the element in the second component (or in the second part, or at the second interface)”, it means that the concentration of the element measured at an arbitrary point in the first component (or in the first part, or at the first interface) is greater than the concentration of the element measured at an arbitrary point in the second component (or in the second part, or at the second interface). For example, the concentration of the element at half the thickness of the first component is greater than the concentration of the element at half the thickness of the second component. For example, the maximum concentration value of the element in the first component is greater than the maximum concentration value of the element in the second component, but the present disclosure is not limited thereto. For example, the concentration of the element measured at a first point in the first component is greater than the concentration of the element measured at a second point in the second component, and the concentration of the element measured at a third point different from the first point in the first component may be less than or equal to the concentration of the element measured at the second point in the second component. In addition, when it is described that “the concentration of an element in the first component is greater than the concentration of the element in the second component”, it includes the case where the second component does not substantially include the element. In other words, the description includes the case where the concentration of the element in the first component is greater than the concentration of the element in the second component, and the concentration of the element in the second component is substantially zero.

In some embodiments, the electronic device of the present disclosure may include a display module, a back light module, an antenna module, a sensing module, or a titling module, but the present disclosure is not limited thereto. The electronic device may be a foldable or flexible electronic device. The display module may be a non-self-luminous display module or a self-luminous display module. The antenna module may be a liquid-crystal antenna module or a non-liquid-crystal antenna module. The sensing device may be a sensing module for sensing capacitance, light, heat, or ultrasonic waves, but the present disclosure is not limited thereto. The electronic elements may include passive elements and active elements, such as capacitors, resistors, inductors, diodes, transistors, and the like. The diodes may include light-emitting diodes or photodiodes. The light-emitting diodes may include, for example, organic light-emitting diodes (OLEDs), mini light-emitting diodes (mini LEDs), micro light-emitting diodes (micro LEDs), or quantum dot light-emitting diodes (quantum dot LED), but the present disclosure is not limited thereto. The titling module may be, for example, a display titling module or an antenna titling module, but the present disclosure is not limited thereto.

In addition, the shape of the electronic device may be rectangular, circular, polygonal, a shape with curved edges, or another suitable shape. The electronic device may have a peripheral system, such as a processing system, a driving system, a controlling system, a light source system, a shelf system, or the like to support the display module or the titling module.

It should be understood that, for clarity of explanation, some elements of the electronic device may be omitted in the drawings, and some elements are schematically illustrated. In some embodiments, additional elements may be added to the electronic device described below. In other embodiments, some elements of the electronic device described below may be replaced or omitted.

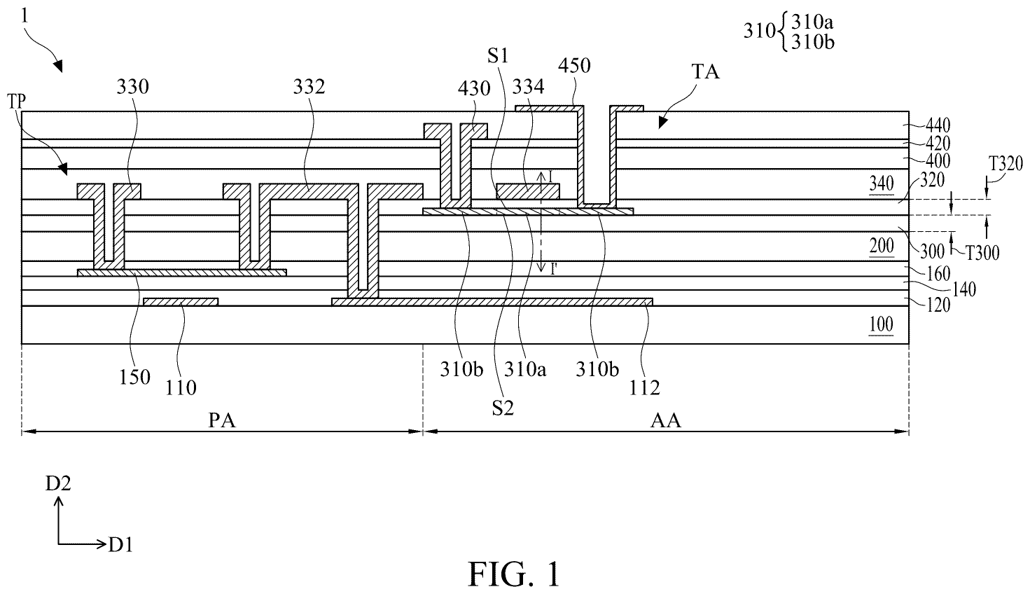

Referring to FIG. 1, which is a schematic cross-sectional view of an electronic device 1 according to some embodiments of the present disclosure. In some embodiments, as shown in FIG. 1, the electronic device 1 may include an active area AA and a peripheral area PA adjacent to the active area AA. In some embodiments, the active area AA may include a transistor TA and the peripheral area PA may include a transistor TP. In some embodiments, the electronic device 1 may include a substrate 100, a first insulating layer 300, an oxide semiconductor layer 310, a second insulating layer 320, and a gate electrode 334. In some embodiments, the first insulating layer 300 may be disposed on the substrate 100, the oxide semiconductor layer 310 may be disposed on the first insulating layer 300, and the second insulating layer 320 may be disposed on the oxide semiconductor layer 310. In some embodiments, the gate electrode 334 may be disposed on the substrate 100. In some embodiments, the gate electrode 334 may be disposed on the second insulating layer 320 so that the electronic device 1 includes a top gate transistor TA. In other embodiments, the gate electrode 334 may be disposed between the substrate 100 and the first insulating layer 300 so that the electronic device 1 includes a bottom gate transistor TA.

In the following, the electronic device 1 is described in detail.

In some embodiments, as shown in FIG. 1, a substrate 100 is provided. In some embodiments, the substrate 100 may include glass, quartz, sapphire, ceramic, polyimide (PI), polycarbonate (PC), polyethylene terephthalate (PET), polypropylene (PP), other suitable materials, or a combination thereof, but the present disclosure is not limited thereto. In some embodiments, the substrate 100 may include a light-transmissive substrate, a semi-light-transmissive substrate, or an opaque substrate.

In some embodiments, as shown in FIG. 1, a first conductive layer 110 and a first conductive layer 112 may be formed on the substrate 100. In some embodiments, the first conductive layer 110 may be disposed in the peripheral area PA and the first conductive layer 112 may be disposed in the peripheral area PA and the active area AA. In some embodiments, the first conductive layer 110 and the first conductive layer 112 may be formed in the same process or in different processes. In some embodiments, the first conductive layer 110 and the first conductive layer 112 may be the zeroth metal layer (M0 layer).

In some embodiments, each of the first conductive layer 110 and the first conductive layer 112 may include a conductive material. In some embodiments, the conductive material may include metal, metal nitride, semiconductor material, other suitable conductive materials, or a combination thereof, but the present disclosure is not limited thereto. In some embodiments, the conductive material may include gold (Au), nickel (Ni), platinum (Pt), palladium (Pd), iridium (Ir), titanium (Ti), chromium (Cr), tungsten (W), aluminum (Al), copper (Cu), molybdenum (Mo), silver (Ag), magnesium (Mg), alloys thereof, compounds thereof, or a combination thereof, but the present disclosure is not limited thereto. In some embodiments, the conductive material may include a transparent conductive oxide (TCO). For example, the transparent conductive oxide may include indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), other suitable transparent conductive materials, or a combination thereof, but the present disclosure is not limited thereto.

In some embodiments, each of the first conductive layer 110 and the first conductive layer 112 may be formed by a deposition process, an etching process, a patterning process, other suitable processes, or a combination thereof. For example, the deposition process may include a chemical vapor deposition (CVD) process, a sputtering process, an evaporation process, a physical vapor deposition (PVD) process, other suitable deposition processes, or a combination thereof, but the present disclosure is not limited thereto. For example, the etching process may include a dry etching, a wet etching, other suitable etching processes, or a combination thereof, but the present disclosure is not limited thereto.

In some embodiments, as shown in FIG. 1, a dielectric layer 120 may be formed on the substrate 100, the first conductive layer 110, and the first conductive layer 112. In some embodiments, the dielectric layer 120 may include an oxide such as silicon oxide, a nitride such as silicon nitride, an oxynitride such as silicon oxynitride, other suitable buffer materials, or a combination thereof, but the present disclosure is not limited thereto. In some embodiments, the dielectric layer 120 may be formed by the aforementioned deposition process or other suitable processes. For example, the dielectric layer 120 may include silicon nitride. In some embodiments, as shown in FIG. 1, a dielectric layer 140 may be formed on the dielectric layer 120. In some embodiments, the materials and formation methods of the dielectric layer 140 may be the same as or different from the materials and formation methods of the dielectric layer 120. For example, the dielectric layer 140 may include silicon oxide.

In some embodiments, as shown in FIG. 1, a semiconductor layer 150 may be formed on the dielectric layer 140 and in the peripheral area PA. In some embodiments, the semiconductor layer 150 may include amorphous silicon (a-Si), low temperature polysilicon (LTPS), indium gallium zinc oxide (IGZO), metal oxides, other suitable semiconductor materials, or a combination thereof, but the present disclosure is not limited thereto. For example, the semiconductor layer 150 may include low temperature polysilicon (LTPS). In some embodiments, as shown in FIG. 1, a dielectric layer 160 may be formed on the dielectric layer 140 and the semiconductor layer 150. In some embodiments, the materials and formation methods of the dielectric layer 160 may be the same as or different from the materials and formation methods of the dielectric layer 120. For example, the dielectric layer 160 may include silicon oxide.

In some embodiments, as shown in FIG. 1, a third insulating layer 200 may be formed on the dielectric layer 160. In some embodiments, the materials and formation methods of the third insulating layer 200 may be the same as or different from the materials and formation methods of the dielectric layer 120. For example, the third insulating layer 200 may include silicon nitride. In some embodiments, the third insulating layer 200 may serve as a barrier layer for moisture.

In some embodiments, as shown in FIG. 1, the first insulating layer 300 may be formed on the third insulating layer 200. In some embodiments, the materials and formation methods of the first insulating layer 300 may be the same as or different from the materials and formation methods of the dielectric layer 120. For example, the first insulating layer 300 may include silicon oxide. In some embodiments, the first insulating layer 300 may serve as a bottom insulating layer for the transistor TA in the active area AA. In some embodiments, the first insulating layer 300 may have a first thickness T300 in the normal direction of the substrate 100. In some embodiments, the first thickness T300 may be greater than or equal to 1000 angstroms (Å) and less than or equal to 3000 angstroms (Å). For example, the first thickness T300 may be 1000 Å, 1200 Å, 1400 Å, 1500 Å, 1600 Å, 1800 Å, 2000 Å, 3000 Å, or any value or any range of values between the aforementioned values, but the present disclosure is not limited thereto.

In some embodiments, as shown in FIG. 1, the oxide semiconductor layer 310 may be formed on the first insulating layer 300. In some embodiments, the oxide semiconductor layer 310 may include ITO, IGO, AZO, SnO, ZnO, IZO, IGZO, ITZO, ATO, other suitable oxide semiconductor materials, or a combination thereof, but the present disclosure is not limited thereto. For example, the oxide semiconductor layer 310 may include IGZO.

In some embodiments, as shown in FIG. 1, the oxide semiconductor layer 310 may have a first part 310a and a second part 310b adjacent to the first part 310a. In some embodiments, the first part 310a may be disposed between the second parts 310b along the first direction D1. In some embodiments, along the normal direction of the substrate 100 (the second direction D2), the first part 310a of the oxide semiconductor layer 310 may correspond to a subsequently formed gate electrode. In some embodiments, the projection range of the subsequently formed gate electrode on the oxide semiconductor layer 310 is the range of the first part 310a. In other words, the part of the oxide semiconductor layer 310 on which the gate electrode is disposed may be referred to as the first part 310a, and the remaining part of the oxide semiconductor layer 310 on which the gate electrode is not disposed may be referred to as the second part 310b. In some embodiments, the first part 310a of the oxide semiconductor layer 310 may serve as a channel region of the transistor TA in the active area AA, and the second part 310b of the oxide semiconductor layer 310 may serve as a conductive region of the transistor TA. In some embodiments, the second part 310b may be a doped region, such as an N-type heavily doped region (N⁺ region) doped with N-type dopants, so that the oxide semiconductor layer 310 is electrically connected to other components, but the present disclosure is not limited thereto.

In some embodiments, as shown in FIG. 1, the second insulating layer 320 may be formed on the first insulating layer 300 and the oxide semiconductor layer 310. In some embodiments, the materials and formation methods of the second insulating layer 320 may be the same as or different from the materials and formation methods of the dielectric layer 120. For example, the second insulating layer 320 may include silicon oxide. In some embodiments, the second insulating layer 320 may serve as a gate insulating layer. In some embodiments, the second insulating layer 320 may have a second thickness T320 in the normal direction of the substrate 100. In some embodiments, the second thickness T320 may be greater than or equal to 300 angstroms (Å) and less than or equal to 1500 angstroms (Å). For example, the second thickness T320 may be 300 Å, 400 Å, 500 Å, 600 Å, 700 Å, 800 Å, 1000 Å, 1500 Å, or any value or any range of values between the aforementioned values, but the present disclosure is not limited thereto.

In some embodiments, the second thickness T320 of the second insulating layer 320 may be less than the first thickness T300 of the first insulating layer 300. In some embodiments, the ratio of the second thickness T320 to the first thickness T300 (the second thickness T320/the first thickness T300) may be greater than or equal to 0.3 and less than or equal to 0.7. For example, the ratio of the second thickness T320 to the first thickness T300 may be 0.3, 0.35, 0.4, 0.45, 0.5, 0.55, 0.6, 0.65, 0.7, or any value or any range of values between the aforementioned values, but the present disclosure is not limited thereto. For example, the ratio of the second thickness T320 to the first thickness T300 may be ranged from (in the range of) 0.3 to 0.7, in the range of 0.3 to 0.6, in the range of 0.4 to 0.5, or any value or any range of values between the aforementioned values, but the present disclosure is not limited thereto.

In some embodiments, as shown in FIG. 1, a second conductive layer 330, a second conductive layer 332, and the gate electrode 334 may be formed on the second insulating layer 320. In some embodiments, the second conductive layer 330 and the second conductive layer 332 may be disposed in the peripheral area PA, and the gate electrode 334 may be disposed in the active area AA. In some embodiments, the gate electrode 334 may overlap the first part 310a of the oxide semiconductor layer 310 in the normal direction of the substrate 100, and the gate electrode 334 may not overlap the second part 310b of the oxide semiconductor layer 310. In some embodiments, each of the second conductive layer 330, the second conductive layer 332, and the gate electrode 334 may include the aforementioned conductive material. In some embodiments, the second conductive layer 330, the second conductive layer 332, and the gate electrode 334 may be formed in the same process or in different processes. In some embodiments, the second conductive layer 330, the second conductive layer 332, and the gate electrode 334 may be the first metal layer (M1 layer). In some embodiments, the second conductive layer 330 may serve as a source electrode of the transistor TP in the peripheral area PA, and the second conductive layer 332 may serve as a drain electrode of the transistor TP in the peripheral area PA. In some embodiments, the gate electrode 334 may be the gate electrode of the transistor TA in the active area AA.

In some embodiments, as shown in FIG. 1, a dielectric layer 340 may be formed on the second insulating layer 320, the second conductive layer 330, the second conductive layer 332, and the gate electrode 334. In some embodiments, the materials and formation methods of the dielectric layer 340 may be the same as or different from the materials and formation methods of the dielectric layer 120. For example, the dielectric layer 340 may include silicon oxide. In some embodiments, as shown in FIG. 1, a fourth insulating layer 400 may be formed on the dielectric layer 340. In some embodiments, the materials and formation methods of the fourth insulating layer 400 may be the same as or different from the materials and formation methods of the third insulating layer 200. For example, the fourth insulating layer 400 may include silicon nitride. In some embodiments, the fourth insulating layer 400 may serve as a barrier layer for moisture.

In some embodiments, as shown in FIG. 1, a dielectric layer 420 may be formed on the fourth insulating layer 400. In some embodiments, the materials and formation methods of the dielectric layer 420 may be the same as or different from the materials and formation methods of the dielectric layer 120. For example, the dielectric layer 420 may include silicon oxide. In some embodiments, as shown in FIG. 1, a third conductive layer 430 may be formed on the dielectric layer 420. In some embodiments, the materials and formation methods of the third conductive layer 430 may be the same as or different from the materials and formation methods of the first conductive layer 110. In some embodiments, the third conductive layer 430 may serve as a source electrode of the transistor TA in the active area AA. In some embodiments, as shown in FIG. 1, a dielectric layer 440 may be formed on the dielectric layer 420 and the third conductive layer 430. In some embodiments, the materials and formation methods of the dielectric layer 440 may be the same as or different from the materials and formation methods of the dielectric layer 120. For example, the dielectric layer 440 may include silicon oxide. In some embodiments, as shown in FIG. 1, a third conductive layer 450 may be formed on the dielectric layer 440. In some embodiments, the materials and formation methods of the third conductive layer 450 may be the same as or different from the materials and formation methods of the first conductive layer 110. For example, the third conductive layer 450 may include ITO. In other embodiments, the third conductive layer 450 and the third conductive layer 430 may be disposed on the same layer. For example, the third conductive layer 450 and the third conductive layer 430 may be disposed on the dielectric layer 420. In some embodiments, the third conductive layer 450 may serve as a drain electrode of the transistor TA in the active area AA. In some embodiments, the third conductive layer 430 and the third conductive layer 450 may be a second metal layer (M2 layer).

In some embodiments, the concentration of oxygen (O) in the aforementioned layer including silicon oxide (for example, the first insulating layer 300, the second insulating layer 320) may be 6E+21˜9E+21 atoms/cubic centimeters (atoms/c.c.). For example, the concentration of oxygen (O) in the layer including silicon oxide may be 6E+21, 7E+21, 8E+21, 9E+21, or any value or any range of values between the aforementioned values, but the present disclosure is not limited thereto. In some embodiments, the concentration of oxygen (O) in the aforementioned layer including silicon nitride (for example, the third insulating layer 200, the fourth insulating layer 400) may be 6E+20˜8E+20 atoms/cubic centimeters (atoms/c.c.). For example, the concentration of oxygen (O) in the layer including silicon nitride may be 6E+20, 7E+20, 8E+20, or any value or any range of values between the aforementioned values, but the present disclosure is not limited thereto. In some embodiments, the ratio of the concentration of O in the silicon oxide layer to the concentration of O in the silicon nitride layer (concentration of O in the silicon oxide layer/concentration of O in the silicon nitride layer) may be 7 to 15. For example, the ratio of the concentration of O in the silicon oxide layer to the concentration of O in the silicon nitride layer may be 7, 8, 9, 10, 11, 12, 13, 14, 15, or any value or any range of values between the aforementioned values, but the present disclosure is not limited thereto. Accordingly, since moisture (water vapor) cannot easily diffuse from the low O concentration layer to the high O concentration layer, the third insulating layer 200 and the fourth insulating layer 400 may serve as barrier layers for moisture to protect the oxide semiconductor layer 310 between the third insulating layer 200 and the fourth insulating layer 400 from being damaged by the moisture. Furthermore, since the density of the silicon nitride layer is higher than the density of the silicon oxide layer, the third insulating layer 200 and the fourth insulating layer 400 may physically isolate moisture to protect the oxide semiconductor layer 310 from being damaged by the moisture.

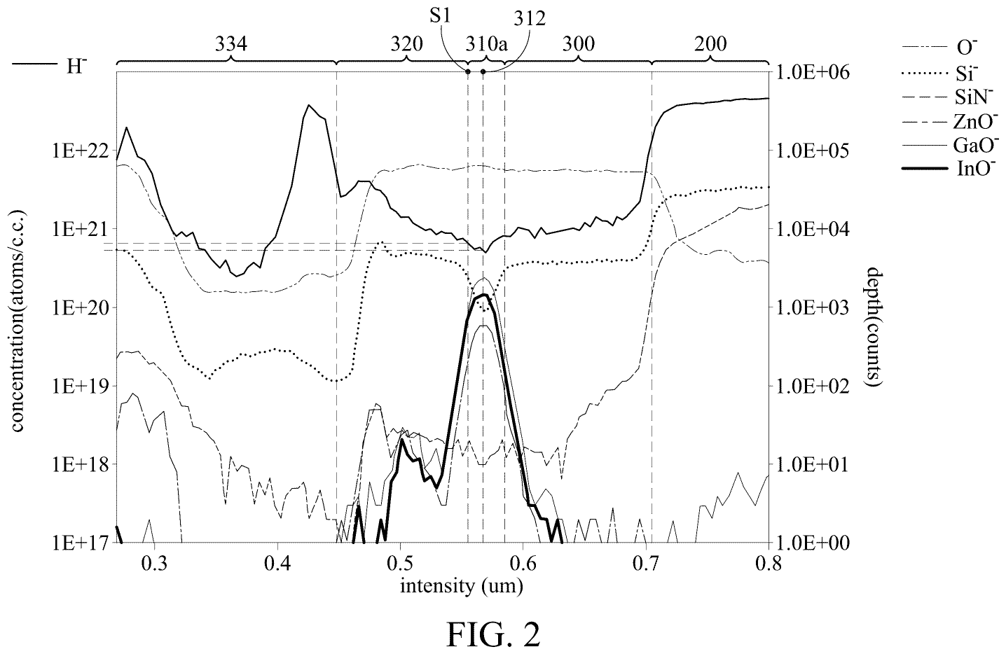

In the following, the electronic device 1 may be used as an example to illustrate the results of elemental analysis, but the present disclosure is not limited thereto. For ease of explanation, different components are marked in subsequent FIGS. 2 to 8 respectively, but subsequent FIGS. 2 to 8 substantially represent the same analysis results.

Referring to FIGS. 2 to 8, which are respectively schematic diagrams of elemental analysis of the electronic device 1 according to some embodiments of the present disclosure. FIGS. 2 to 8 respectively show schematic diagrams of elemental analysis performed by TOF-SIMS analysis in negative ion mode along the cross-section I-I′ of the electronic device 1 shown in FIG. 1. The minimum analyzable value of the concentration analyzed by TOF-SIMS in negative ion mode is in the range of 1.0E+19 atoms/cubic centimeter (atoms/c.c.) to 1.0E+20 atoms/cubic centimeter (atoms/c.c.), wherein, the concentration of hydrogen (H⁻) ions refer to the vertical axis coordinate on the left side (concentration (atoms/cubic centimeter (atoms/c.c.))), and their concentrations are the concentrations after quantitative analysis. The contents of O⁻, Si⁻, SiN⁻, ZnO⁻, GaO⁻, and InO⁻ refer to the vertical axis coordinate on the right side (intensity (counts)), and their intensities are the counts after qualitative analysis. Wherein the horizontal axis coordinate represents the depth (μm) along the direction opposite to the second direction D2. For example, the horizontal axis coordinate represents a direction from the gate electrode 334 toward the third insulating layer 200. In some embodiments, the concentration of hydrogen (H⁻) ions analyzed by TOF-SIMS in negative ion mode is equivalent to the concentration of hydrogen.

In some embodiments, as shown in FIGS. 1 and 2, in the spectrum measured by TOF-SIMS, a concentration of H⁻ at a first interface S1 between the second insulating layer 320 and the first part 310a of the oxide semiconductor layer 310 is greater than a concentration of H⁻ at the center portion 312 of the first part 310a of the oxide semiconductor layer 310. In some embodiments, the center portion 312 of the first part 310a is defined as a location corresponding to the peak of the intensity of InO⁻ shown in FIG. 2. That is, the center portion 312 of the first part 310a may correspond to the maximum value of the intensity of InO⁻. In some embodiments, the first interface S1 may be defined as a location corresponding to 80% of the peak of the intensity of InO⁻ shown in FIG. 2 and having a depth less than the center portion 312. That is, the first interface S1 may correspond to 80% of the maximum value of the intensity of InO⁻, and the first interface S1 is further away from the substrate 100 than the center portion 312, but the present disclosure is not limited thereto.

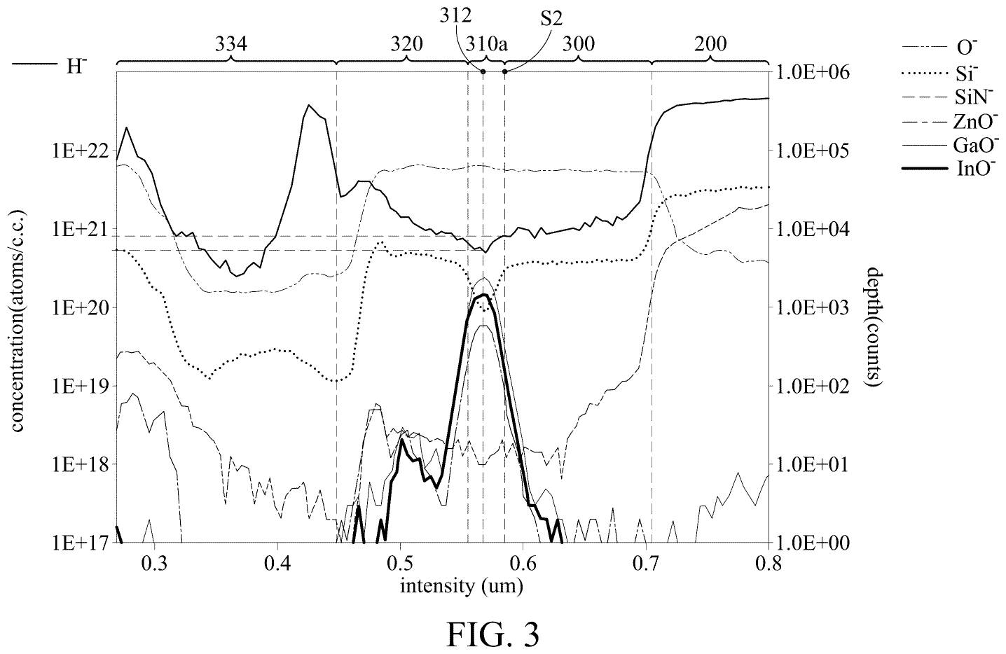

In some embodiments, as shown in FIGS. 1 and 3, in the spectrum measured by TOF-SIMS, a concentration of H⁻ at a second interface S2 between the first insulating layer 300 and the first part 310a of the oxide semiconductor layer 310 is greater than the concentration of H⁻ at the center portion 312 of the first part 310a of the oxide semiconductor layer 310. In some embodiments, the second interface S2 may be defined as a location corresponding to 80% of the peak of the intensity of InO⁻ shown in FIG. 3 and having a depth that is deeper than the center portion 312. For example, the second interface S2 may correspond to 80% of the maximum value of the intensity of InO⁻, and the second interface S2 is closer to the substrate 100 than the center portion 312, but the present disclosure is not limited thereto.

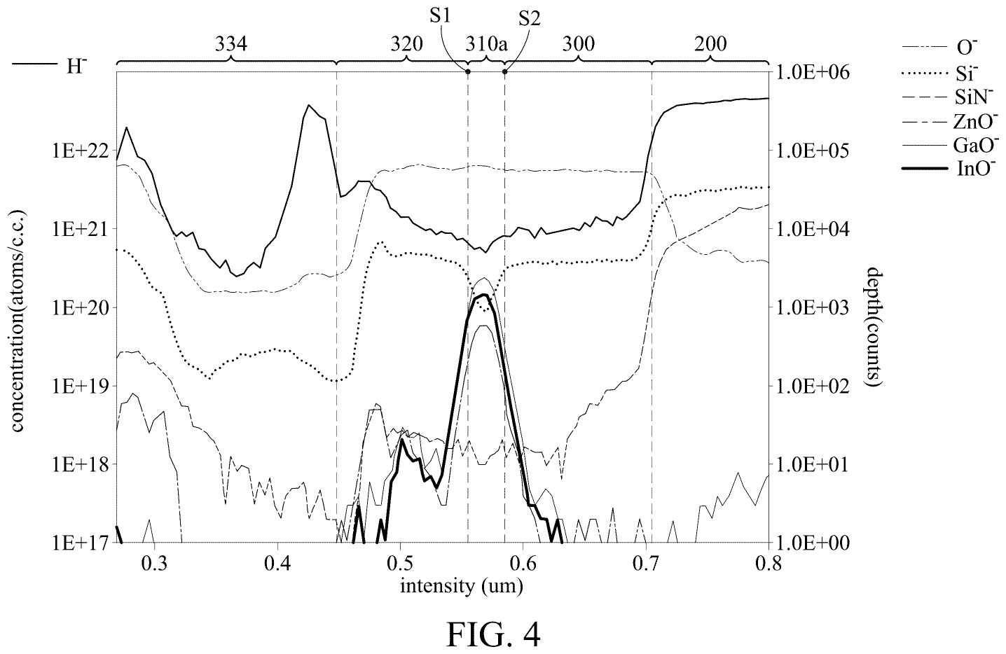

In some embodiments, as shown in FIGS. 1 and 4, in the spectrum measured by TOF-SIMS, the concentration of H⁻ at the first interface S1 is less than the concentration of H⁻ at the second interface S2. Accordingly, since the channel region of the transistor TA in the active area AA is formed on the first interface S1, when the concentration of H⁻ at the first interface S1 is lower, it may avoid the threshold voltage (Vth) of the transistor TA from shifting toward the negative voltage.

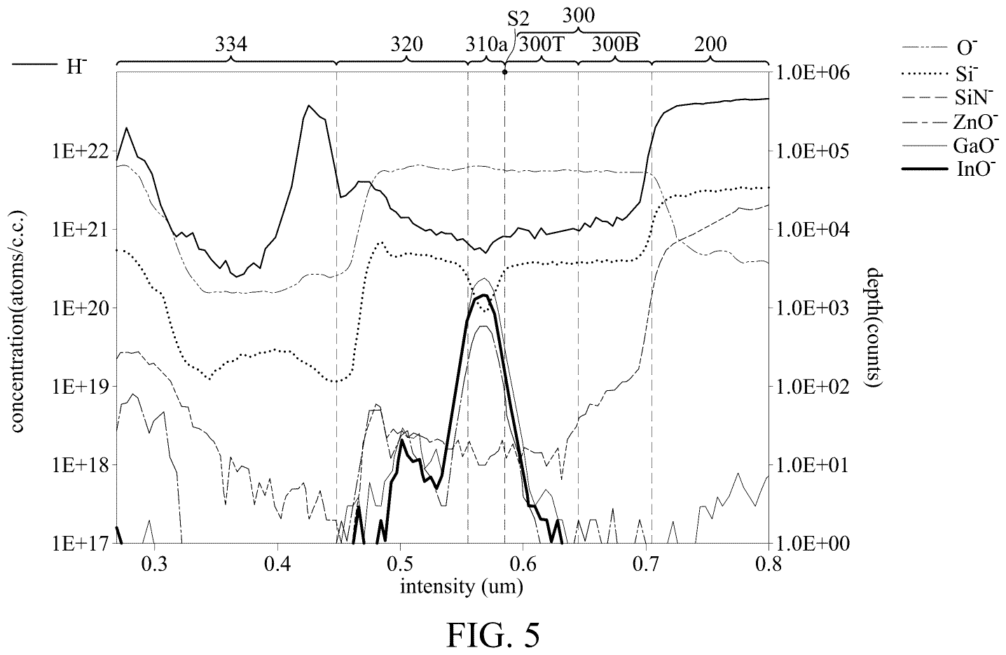

In some embodiments, as shown in FIGS. 1 and 5, in some embodiments, based on the first thickness T300 of the first insulating layer 300 in the second direction D2, the first insulating layer 300 is divided into an upper part 300T and a lower part 300B, and the concentration of H⁻ of the upper part 300T may be less than the concentration of H⁻ of the lower part 300B. The first insulating layer 300 may have the upper part 300T and the lower part 300B disposed below the upper part 300T. In some embodiments, in the spectrum measured by TOF-SIMS, the concentration of H⁻ at a bottom surface of the first insulating layer 300 is greater than the concentration of H⁻ at the second interface S2 between the first insulating layer 300 and the first part 310a of the oxide semiconductor layer 310. In some embodiments, the bottom surface of the first insulating layer 300 is defined as the location in the lower part 300B of the first insulating layer 300 that corresponds to the maximum value of the slope of the concentration of H⁻ with respect to the depth. That is, the bottom surface of the first insulating layer 300 is the location where the slope in the lower part 300B of the first insulating layer 300 in the curve of the concentration of H⁻ is maximum.

In detail, since the oxide semiconductor layer 310 is easily affected by the concentration of H⁻ in adjacent components, the concentration of H⁻ in components adjacent to the oxide semiconductor layer 310 needs to be adjusted. When the concentration of H⁻ in the adjacent component is too high to diffuse into the oxide semiconductor layer 310, the conductivity of the first part 310a of the oxide semiconductor layer 310 will be too high. Therefore, an unnecessary conduction may be occurred in the first part 310a of the oxide semiconductor layer 310 so that the transistor TA in the active area AA may be deteriorated. Once the unnecessary conduction has occurred in the first part 310a of the oxide semiconductor layer 310 serving as the channel region, the switching of the transistor TA may not be controlled by the gate electrode 334. Thus, the present disclosure improves the electrical performance and/or stability of the transistor by controlling the concentration of H⁻ in each component. For example, after performing a reliability test under high temperature and high humidity conditions, unnecessary conduction will not occur. Accordingly, the present disclosure prevents H⁻ in the upper part 300T of the first insulating layer 300 close to the oxide semiconductor layer 310 from diffusing into the oxide semiconductor layer 310 by adjusting the concentration of H⁻ in the first insulating layer 300.

Furthermore, since H⁻ in the lower part 300B of the first insulating layer 300 away from the oxide semiconductor layer 310 is less likely to affect the oxide semiconductor layer 310, the speed of initial formation of the first insulating layer 300 may be increased and reduced process time. For example, when the first insulating layer 300 is initially formed, N₂ may be used to catalyze the reaction of SiH₄ and N₂O to increase the speed of formation the first insulating layer 300. Next, N₂ is removed before the first insulating layer 300 is completed (without N₂ to catalyze), and SiH₄ and N₂O are used to be reacted thereby reducing the concentration of H⁻ in the upper part 300T of the first insulating layer 300 adjacent to the oxide semiconductor layer 310.

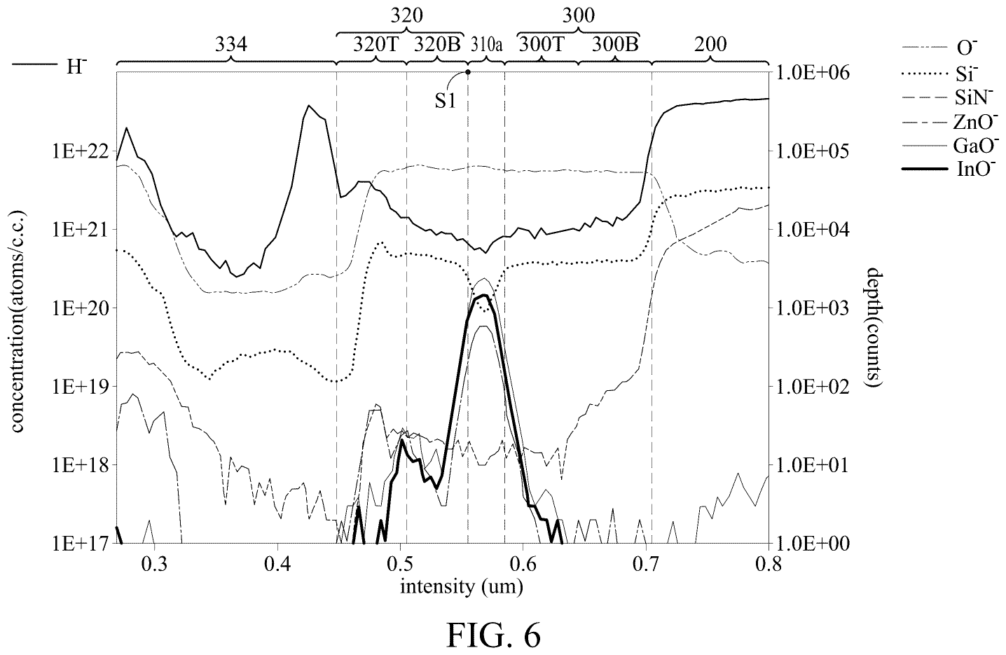

In some embodiments, as shown in FIGS. 1 and 6, in some embodiments, based on the second thickness T320 of the second insulating layer 320 in the second direction D2, the second insulating layer 320 is divided into an upper part 320T and a lower part 320B, and the concentration of H⁻ of the upper part 320T may be greater than the concentration of H⁻ of the lower part 320B. The second insulating layer 320 may have the upper part 320T and the lower part 320B disposed below the upper part 320T. In the spectrum measured by TOF-SIMS, the concentration of H⁻ at a top surface of the second insulating layer 320 is greater than the concentration of H⁻ at the first interface S1 between the second insulating layer 320 and the first part 310a of the oxide semiconductor layer 310. In some embodiments, the top surface of the second insulating layer 320 is defined as the location in the upper part 320T of the second insulating layer 320 that corresponds to the maximum value of the slope of the concentration of H⁻ with respect to the depth. That is, the top surface of the second insulating layer 320 is the location where the slope in the upper part 320T of the second insulating layer 320 in the curve of concentration of H⁻ is maximum. Accordingly, the present disclosure prevents H⁻ in the lower part 320B of the second insulating layer 320 close to the oxide semiconductor layer 310 from diffusing into the oxide semiconductor layer 310 by adjusting the concentration of H⁻ in the second insulating layer 320.

Furthermore, since the concentration of H⁻ of the upper part 320T of the second insulating layer 320 may be greater than the concentration of H⁻ of the lower part 320B of the second insulating layer 320, the second insulating layer 320 may effectively passivate dangling bonds at the first interface S1 between the oxide semiconductor layer 310 and the second insulating layer 320 to avoid defects in the oxide semiconductor layer 310, thereby improving the electrical performance and/or stability of the transistor TA.

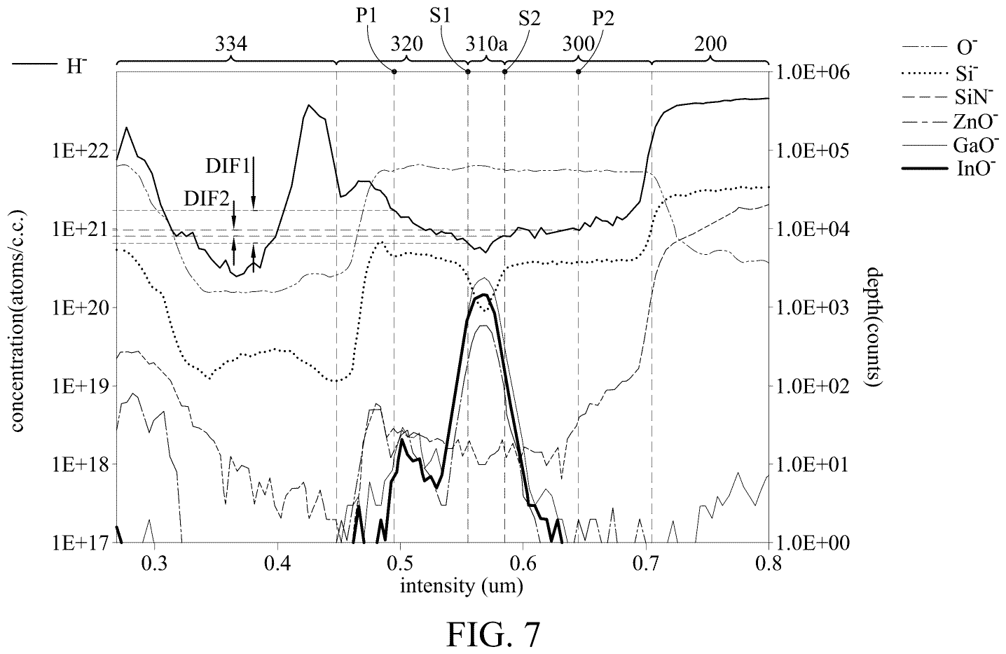

In some embodiments, as shown in FIGS. 1 and 7, the slope of the concentration of H⁻ in the first insulating layer 300 may be less than the slope of the concentration of H⁻ in the second insulating layer 320. In some embodiments, in the spectrum measured by TOF-SIMS, a first difference DIF1 between the concentration of H⁻ at the first interface S1 and a concentration of H⁻ at a first location P1 above the first interface S1 by 600 angstroms (Å) is greater than a second difference DIF2 between the concentration of H⁻ at the second interface S2 and a concentration of H⁻ at a second location P2 under the second interface S2 by 600 angstroms (Å). Since H⁻ in the first insulating layer 300 does not need to be used to passivate the dangling bonds at the second interface S2, the first difference DIF1 may be greater than the second difference DIF2. Accordingly, H⁻ in the first insulating layer 300 and the second insulating layer 320 close to the oxide semiconductor layer 310 is prevented from diffusing into the oxide semiconductor layer 310, and the dangling bonds are effectively passivated.

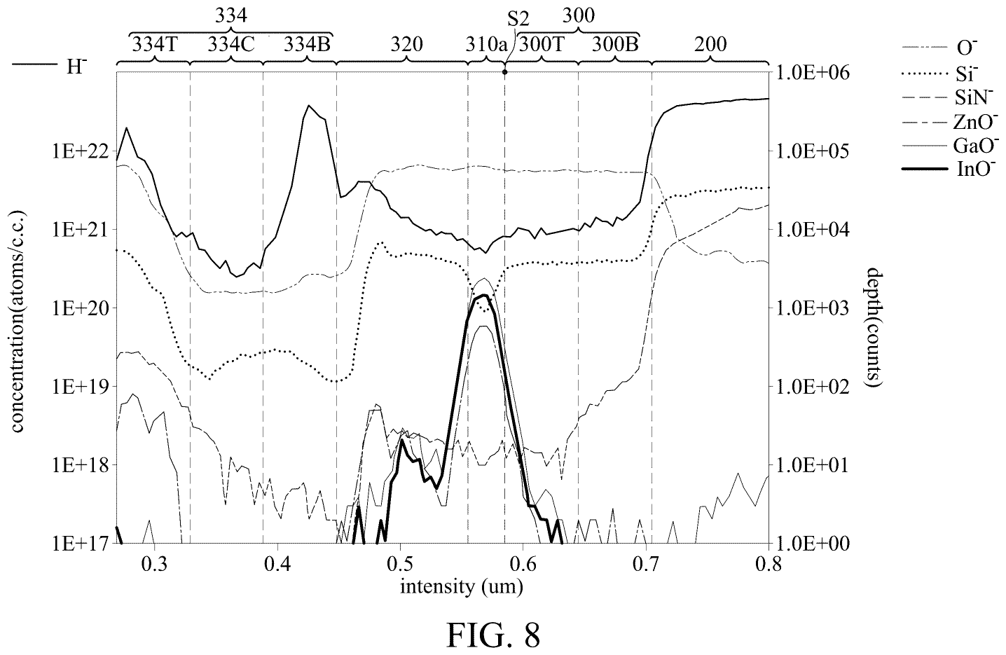

In some embodiments, as shown in FIGS. 1 and 8, in the spectrum measured by TOF-SIMS, the first insulating layer 300 has the upper part 300T and the lower part 300B, and an intensity of SiN⁻ at the lower part 300B is greater than an intensity of SiN⁻ at the upper part 300T. In some embodiments, the two interfaces defined by the bottom surface of the first insulating layer 300 and the second interface S2 are used as the upper interface and the lower interface of the first insulating layer 300. Based on the first thickness T300 of the first insulating layer 300 in the second direction D2, the first insulating layer 300 is divided into the upper part 300T and the lower part 300B. In some embodiments, the SiN⁻ at the lower part 300B may come from SiN-bonds generated by using N₂ to catalyze during the initial formation of the first insulating layer 300. Accordingly, the speed of formation of the first insulating layer 300 may be increased.

In some embodiments, as shown in FIGS. 1 and 8, in some embodiments, in the spectrum measured by TOF-SIMS, the gate electrode 334 may have an upper part 334T, a lower part 334B, and a middle part 334C disposed between the upper part 334T and the lower part 334B. In some embodiments, based on the thickness of the gate electrode 334 in the second direction D2, the gate electrode 334 is divided into the upper part 334T, the middle part 334C, and the lower part 334B. In some embodiments, the concentration of H⁻ at the lower part 334B is greater than the concentration of H⁻ at the middle part 334C. In some embodiments, the concentration of H⁻ at the upper part 334T is greater than the concentration of H⁻ at the middle part 334C. In some embodiments, the concentration of H⁻ at the lower part 334B is greater than the concentration of H⁻ at the upper part 334T.

In summary, according to some embodiments of the present disclosure, an electronic device is provided. The electronic device may improve the electrical performance and/or stability of electronic device by adjusting parameters (for example, kinds of material, concentration of H⁻, concentration of SiN⁻) of components adjacent to the oxide semiconductor layer (for example, the first insulating layer, the second insulating layer, the gate electrode, the third insulating layer, and the fourth insulating layer). For example, the first insulating layer and the second insulating layer of the present disclosure may prevent the oxide semiconductor layer in the transistor from deteriorating and/or prevent the threshold voltage from shifting toward the negative voltage. For example, the third insulating layer and the fourth insulating layer of the present disclosure may prevent the oxide semiconductor layer from being damaged by moisture.

The features among the various embodiments may be arbitrarily combined as long as they do not violate or conflict with the spirit of the disclosure. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic device, comprising:
a substrate;
a first insulating layer disposed on the substrate;
an oxide semiconductor layer disposed on the first insulating layer, having a first part and a second part adjacent to the first part;
a second insulating layer disposed on the oxide semiconductor layer; and
a gate electrode disposed on the substrate and overlapped with the first part of the oxide semiconductor layer;
wherein a concentration of H⁻ at a first interface between the second insulating layer and the first part is greater than a concentration of H⁻ at a center portion of the first part in a spectrum measured by TOF-SIMS.

2. The electronic device according to claim 1, wherein a concentration of H⁻ at a second interface between the first insulating layer and the first part is greater than the concentration of H⁻ at the center portion of the first part in the spectrum measured by TOF-SIMS.

3. The electronic device according to claim 2, wherein the concentration of H⁻ at the first interface is less than the concentration of H⁻ at the second interface in the spectrum measured by TOF-SIMS.

4. The electronic device according to claim 2, wherein a concentration of H⁻ at a bottom surface of the first insulating layer is greater than the concentration of H⁻ at the second interface between the first insulating layer and the first part in the spectrum measured by TOF-SIMS.

5. The electronic device according to claim 4, wherein a concentration of H⁻ at a top surface of the second insulating layer is greater than the concentration of H⁻ at the first interface between the second insulating layer and the first part in the spectrum measured by TOF-SIMS.

6. The electronic device according to claim 2, wherein a difference between the concentration of H⁻ at the first interface and a concentration of H⁻ at a first location above the first interface by 600 angstroms is greater than a difference between the concentration of H⁻ at the second interface and a concentration of H⁻ at a second location under the second interface by 600 angstroms in the spectrum measured by TOF-SIMS.

7. The electronic device according to claim 2, wherein the first insulating layer has an upper part and a lower part, an intensity of SiN⁻ at the lower part is greater than an intensity of SiN⁻ at the upper part in the spectrum measured by TOF-SIMS.

8. The electronic device according to claim 1, further comprising a third insulating layer disposed under the first insulating layer, wherein the first insulating layer comprises silicon oxide, and the third insulating layer comprises silicon nitride.

9. The electronic device according to claim 1, further comprising a fourth insulating layer disposed on the second insulating layer, wherein the second insulating layer comprises silicon oxide, and the fourth insulating layer comprises silicon nitride.

10. The electronic device according to claim 1, wherein the first insulating layer has a first thickness, the second insulating layer has a second thickness, and the second thickness is less than the first thickness.

11. The electronic device according to claim 10, wherein a ratio of the second thickness to the first thickness is ranged from 0.3 to 0.7.

12. The electronic device according to claim 11, wherein the ratio is ranged from 0.3 to 0.6.

13. The electronic device according to claim 12, wherein the ratio is ranged from 0.4 to 0.5.

14. The electronic device according to claim 1, wherein the gate electrode has an upper part, a lower part and a middle part disposed therebetween, a concentration of H⁻ at the lower part is greater than a concentration of H⁻ at the middle part in the spectrum measured by TOF-SIMS.

15. The electronic device according to claim 14, wherein a concentration of H⁻ at the upper part is greater than the concentration of H⁻ at the middle part in the spectrum measured by TOF-SIMS.

16. The electronic device according to claim 15, wherein the concentration of H⁻ at the lower part is greater than the concentration of H⁻ at the upper part in the spectrum measured by TOF-SIMS.

17. The electronic device according to claim 1, wherein the gate electrode is disposed on the second insulating layer.

18. The electronic device according to claim 1, wherein the gate electrode is disposed between the substrate and the first insulating layer.

19. The electronic device according to claim 1, wherein the first insulating layer has an upper part and a lower part, a concentration of H of the upper part is less than a concentration of H of the lower part in the spectrum measured by TOF-SIMS.

20. The electronic device according to claim 1, wherein the second insulating layer has an upper part and a lower part, a concentration of H of the upper part is greater than a concentration of H⁻ of the lower part in the spectrum measured by TOF-SIMS.
